(19) United States
(12) Patent Application Publication
(10) Pub. No.: US 2008/0054418 A1
(43) Pub. Date: Mar. 6, 2008

(54) CHIP CARRIER WITH SIGNAL COLLECTION TAPE AND FABRICATION METHOD THEREOF

(75) Inventors: Chun-Chi Chen, Kaohsiung City (TW); Kang-Wei Ma, Kaohsiung (TW)

Correspondence Address: J C PATENTS, INC., 4 VENTURE, SUITE 250, IRVINE, CA, 92618, US

(73) Assignee: ADVANCED SEMICONDUCTOR ENGINEERING, INC., Kaohsiung (TW)

(21) Appl. No.: 11/832,174

(22) Filed: Aug. 1, 2007

(30) Foreign Application Priority Data
Sep. 6, 2006 (TW) 95132963

(51) Int. Cl. H01L 23/495

(52) U.S. Cl. 257/666; 257/E23.031

(57) ABSTRACT

A chip carrier for carrying a chip including a carrier and at least one signal collection tape is provided. The carrier has a surface, a die pad and a plurality of inner leads surrounding the die pad, and the signal collection tape is disposed on the surface of the carrier, and is electrically connected to the chip. The signal collection tape is used to replace the conventional power ring and ground ring and to decrease the length of bonding wire, thus reducing the package size.

### CROSS-REFERENCE TO RELATED APPLICATION

This application claims the priority benefit of Taiwan application serial no. 95132963, filed on Sep. 6, 2006. All disclosure of the Taiwan application is incorporated herein by reference.

### BACKGROUND OF THE INVENTION

1. Field of the Invention

The present invention relates to a chip carrier. More particularly, the present invention relates to a chip carrier having a signal collection tape, and a fabrication method thereof.

2. Description of Related Art

Referring to FIG. 1, a conventional chip carrier 100 for carrying a chip 500 comprises a power ring 110, a ground ring 120, a die pad 130 and a plurality of inner leads 140. The power ring 110 and the ground ring 120 are disposed between the die pad 130 and the inner leads 140, and surround the die pad 130. The chip 500 is disposed on the die pad 130, and is electrically connected to the power ring 110, the ground ring 120 and the inner leads 140 through a plurality of bonding wires 700. However, the design of the power ring 110 and the ground ring 120 has some shortages in application. One of the shortages is the number and length of the bonding wire 700 for connecting the chip 500 and the power ring 110, the ground ring 120 and the inner leads 140 are increased, and therefore the production cost is relatively expensive. Another shortage is that since the power ring 110 and the ground ring 120 are disposed between the die pad 130 and the inner leads 140, the distance between the chip 500 and the inner leads 140 is increased. Therefore, the electrical connection may not be performed within a short distance, and the package size of the chip carrier 100 may not be reduced.

### SUMMARY OF THE INVENTION

The present invention provides a chip carrier for carrying a chip. The chip carrier comprises a carrier and at least one signal collection tape. The carrier has a surface, a die pad and a plurality of electrical contacts surrounding the die pad, and the signal collection tape is disposed on the surface of the carrier for electrically connecting to the chip. In the present invention, the signal collection tape is used to replace the conventional power ring and ground ring, and not only is the fabrication cost of the chip carrier saved, but also the length of bonding wire and the package size are reduced.

The present invention provides a chip carrier, wherein the signal collection tape is disposed on the die pad for electrically connecting the chip with the inner leads.

The present invention provides a chip carrier, wherein the signal collection tape is disposed on the inner leads, for electrically connecting to the chip.

The present invention provides a chip carrier including a carrier and at least one signal collection tape, wherein the carrier includes a surface, a die pad and a plurality of electrical contacts surrounding the die pad. The signal collection tape is disposed on the surface of the carrier for electrically connecting to the chip.

The present invention provides a fabrication method of a chip carrier comprising the following steps. First, a carrier having a surface, a die pad and a plurality of inner leads surrounding the die pad is provided. Then, at least one signal collection tape is placed on the surface of the carrier.

The present invention provides a chip carrier including a carrier and at least a signal collection tape. The carrier includes a surface, a die pad and a plurality of fingers surrounding the die pad. The signal collection tape is disposed on the surface of the carrier for electrically connecting to the chip.

The present invention provides a fabrication method of a chip carrier comprising the following steps. First, a carrier having a surface, a die pad and a plurality of fingers surrounding the die pad is provided. Then, at least one signal collection tape is placed on the surface of the carrier.

The present invention provides a signal collection tape including a base layer and a conductive layer. The base layer includes an adhesive layer and an insulating layer formed on the adhesive layer. The conductive layer is formed on the insulating layer of the base layer and includes a metal layer and an electroplating layer formed on the metal layer.

The present invention provides a fabrication method of a signal collection tape comprising the following steps. First, a base layer comprising an adhesive layer and an insulating layer formed on the adhesive layer is provided. Then, a conductive layer is placed on the insulating layer of the base layer, wherein the conductive layer includes a metal layer and an electroplating layer formed on the metal layer.

### BRIEF DESCRIPTION OF THE DRAWINGS

FIG. 1 is a schematic cross-sectional view showing a conventional chip carrier.

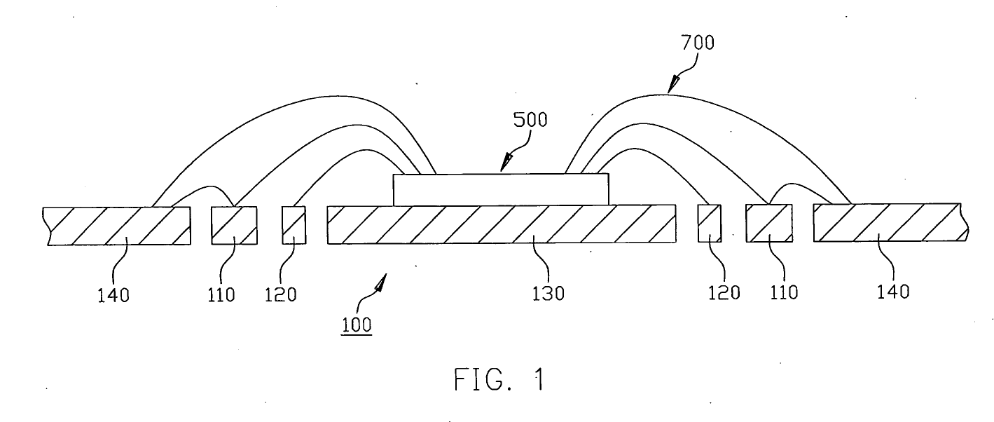

FIG. 2 is a schematic cross-sectional view showing a chip carrier according to the first embodiment of the present invention.

FIG. 3 is a schematic cross-sectional view showing a chip carrier according to an embodiment of the present invention.

FIGS. 4A and 4B are schematic cross-sectional view showing the process flow for fabricating a chip carrier according to the first embodiment of the present invention.

FIGS. 5A and 5B are schematic cross-sectional view showing the process flow for fabricating a signal collection tape according to the first embodiment of the present invention.

FIG. 6 is a schematic cross-sectional view showing a chip carrier according to the second embodiment of the present invention.

FIG. 7 is a schematic cross-sectional view showing a chip carrier according to an embodiment of the present invention.

FIGS. 8A and 8B are schematic cross-sectional view showing the process flow for fabricating a chip carrier according to the second embodiment of the present invention.

### DESCRIPTION OF EMBODIMENTS

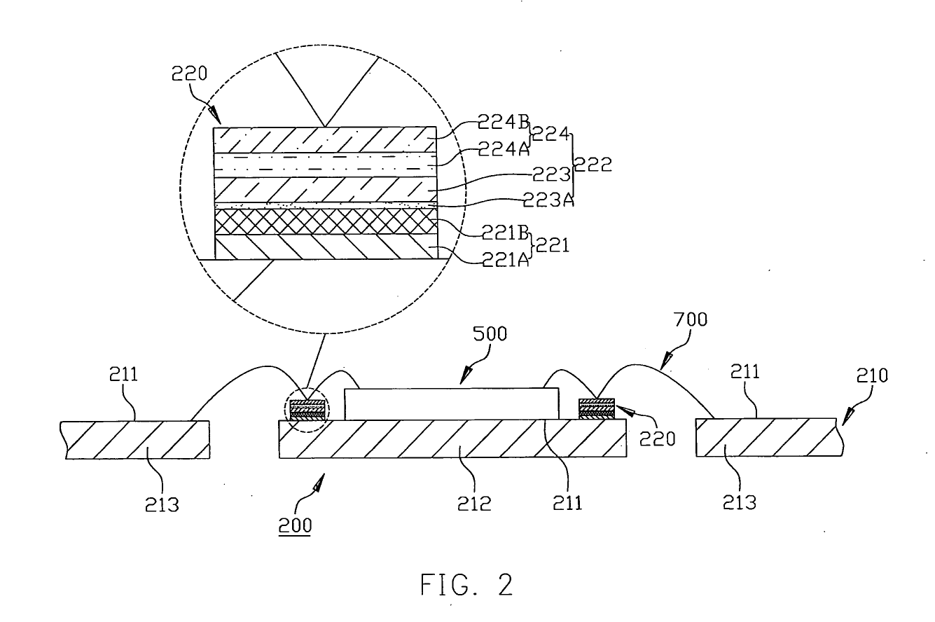

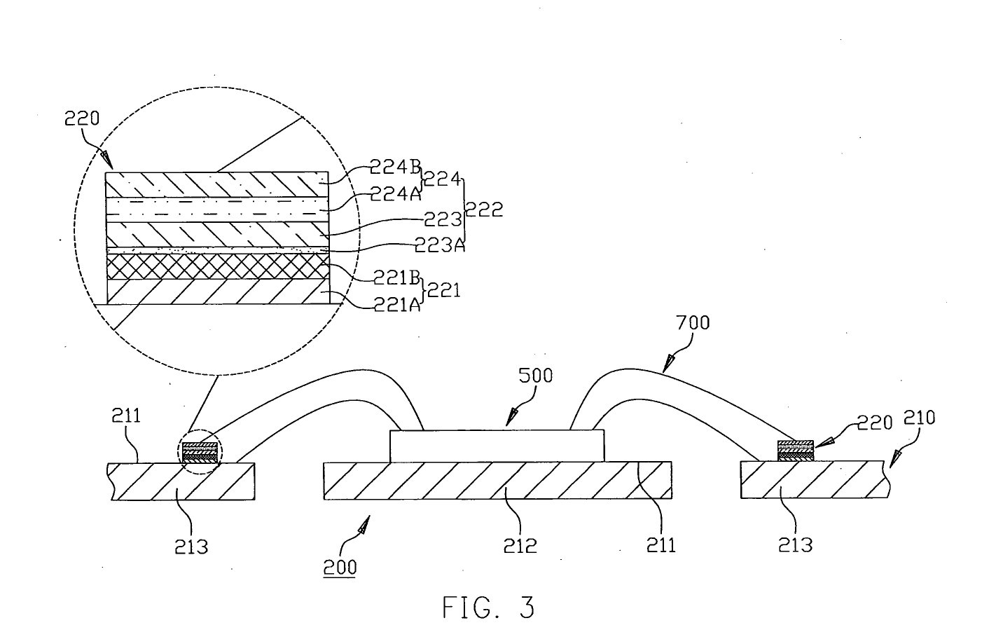

Referring to FIG. 2, a chip carrier 200 for carrying a chip 500 according to the first embodiment includes a carrier 210 and at least a signal collection tape 220. In the present embodiment, the carrier 210 is a lead frame comprising a surface 211, a die pad 212 and a plurality of inner leads 213 serving as electrical contacts. The chip 500 is disposed on the die pad 212. The inner leads 213 surround the die pad 212. The signal collection tape 220 is disposed on the surface 211 of the carrier 210 and is electrically connected to the chip 500 through at least one bonding wire 700. The signal collection tape 220 is not only used to replace the conventional power ring and the ground ring, but also greatly reduces the length of bonding wire 700. In the present embodiment, the signal collection tape 220 is disposed on the die pad 212 for electrically connecting the chip 500 and the inner leads 213. Referring to FIG. 3, in another embodiment, the signal collection tape 220 may be disposed on the inner leads 213, and the bonding wire 700 originally connecting the chip 500 to the conventional power ring or ground ring may be collected in the signal collection tape 220 and electrically connects to other conductive components (e.g. inner leads 213) through the signal collection tape 220. Such that the cost and time for fabricating the power ring or the ground ring may be saved, and the package size of the chip carrier 200 may be reduced.

Referring to FIG. 3 again, in the present embodiment, the signal collection tape 220 includes a base layer 221 and a conductive layer 222. The base layer 221 includes an adhesive layer 221A and an insulating layer 221B formed on the adhesive layer 221A. The signal collection tape is connected to the die pad 212 or the inner leads 213 through the adhesive layer 221A. The insulating layer 221B is used for electrically insulating the conductive layer 222 from the die pad 212 or the inner leads 213. The thickness of the adhesive layer 221A and the insulating layer 221B is preferably between 5˜30 micrometers. The conductive layer 222 is formed on the insulating layer 221B of the base layer 221, and includes a metal layer 223 and an electroplating layer 224. The conductive layer 222 may be a patterned circuit layer. The electroplating layer 224 is formed on the metal layer 223. In the present embodiment, the metal layer 223 is an electrical conductive layer formed by copper foil, and the metal layer 223 includes an adhesive layer 223A. The metal layer 223 may connect the base layer through the adhesive layer 223A. In another embodiment, the metal layer 223 may be directly formed on the insulating layer 221B of the base layer 221 by electroless plating or by sputtering. The thickness of the metal layer 223 formed by electroless plating is less than 1 nanometer, and the thickness of the metal layer 223 is between 0.1 nanometer and 28 micrometers preferably. The electroplating layer 224 includes a nickel layer 224A and a gold layer 224B formed on the nickel layer 224A, wherein the nickel layer 224A is used for increasing the adhesive strength between the gold layer 224B and the metal layer 223. Preferably, the thickness of the nickel layer 224A is between 0.1˜20 micrometers, and the thickness of the gold layer 224B is between 0.1˜5 micrometers.

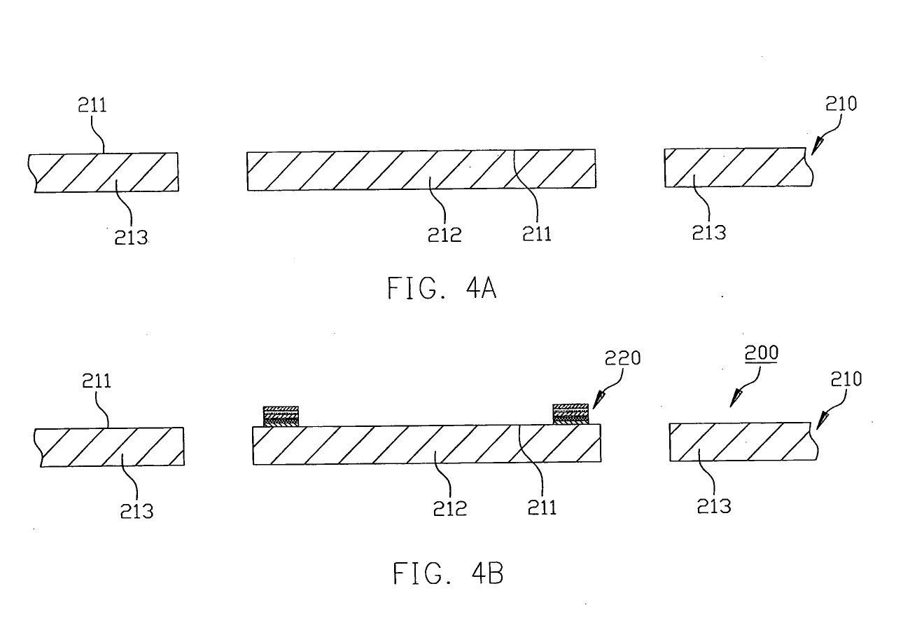

A fabrication method of the chip carrier 200 according to the first embodiment of the present invention is shown in FIGS. 4A and 4B. First, referring to FIG. 4A, a carrier 210, such as a lead frame, is provided, wherein the carrier 210 includes a surface 211, a die pad 212 and a plurality of inner leads 213 surrounding the die pad 212. Next, referring to FIG. 4B, at least one signal collection tape 220 is placed on the surface 211 of the carrier 210, wherein in the present embodiment, the signal collection tape 220 is formed on the die pad 212 for electrically connecting the chip 500 with the inner leads 213. In another embodiment, the collection tape 220 may be formed on the inner leads 213.

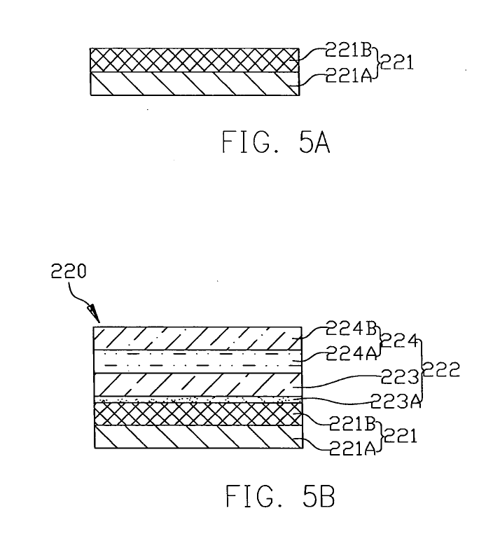

FIGS. 5A and 5B are schematic cross-sectional view showing the process flow for fabricating a signal collection tape according to the first embodiment of the present invention. First, referring to FIG. 5A, a base layer 221 is provided, wherein the base layer 221 comprises an adhesive layer 221A and an insulating layer 221B formed on the adhesive layer 221A. Then, referring to FIG. 5B, a conductive layer 222 is formed on the insulating layer 221b of the base layer 221, wherein the material of the conductive layer 222 is a conductive material. In this embodiment, the conductive layer 222 comprises a metal layer 223 and an electroplating layer 224. The conductive layer 222 may be a patterned circuit layer; and the electroplating layer 224 is formed on the metal layer 223. The signal collection tape 200 of the present invention is fabricated according to these processes.

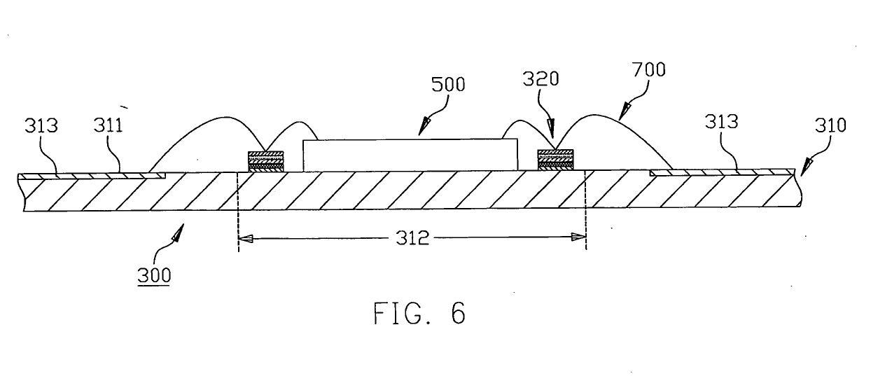

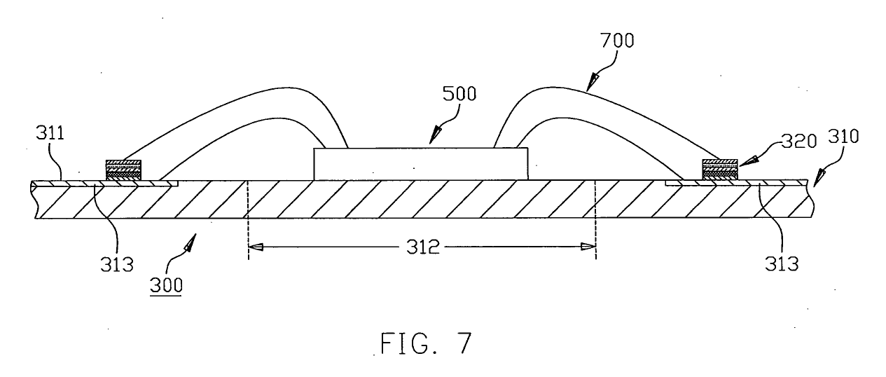

Referring to FIG. 6, in the second embodiment, a chip carrier 300 for carrying a chip 500 includes a carrier 310 and at least one signal collection tape 320. In this embodiment, the carrier 310 is a substrate including a surface 311, a die pad 312 and a plurality of fingers 313. The die pad 312 is used for carrying the chip 500. The fingers 313 surround the die pad 312. The signal collection tape 320 is disposed on the surface 311 of the carrier 310 and electrically connects to the chip 500 through at least one bonding wire 700. The signal collection tape 320 is not only used to replace the conventional power ring and ground ring, but also greatly reduces the length of bonding wire 700. In the present embodiment, the signal collection tape 320 is disposed on the die pad 312 for electrically connecting the chip 500 and the fingers 313. Referring to FIG. 7, in another embodiment, the signal collection tape 320 may be disposed on the fingers 313, and the bonding wire 700 originally connecting the chip 500 to the conventional power ring or ground ring may be collected in the signal collection tape 320 and electrically connects to other conductive components (e.g. fingers 313) through the signal collection tape 320. Such that the cost and time for fabricating the power ring or the ground ring may be saved, and the package size of the chip carrier 300 may be reduced.

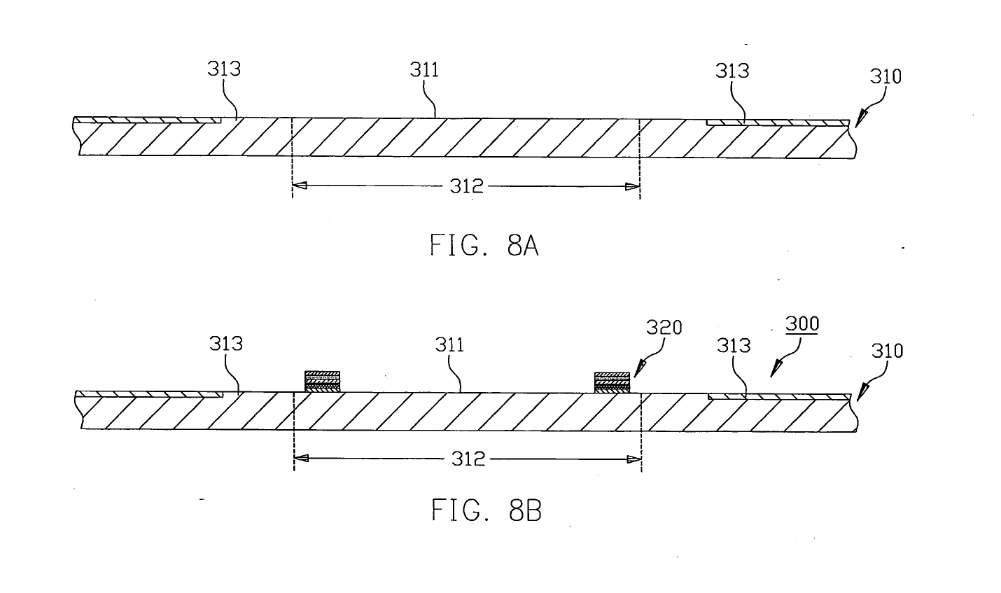

FIGS. 8A and 8B are schematic cross-sectional view showing the process flow for fabricating a chip carrier according to the second embodiment of the present invention. First, referring to FIG. 8A, a carrier 310, such as a substrate, is provided, wherein the carrier 310 includes a surface 311, a die pad 312 and a plurality of finger 313 surrounding the die pad 312. Then, referring to FIG. 8B, at least one signal collection tape 320 is placed on the surface 311 of the carrier 310. The signal collection tape 320 is formed on the die pad 312 for electrically connecting the chip 500 and the fingers 313 in the present embodiment. In another embodiment, the signal collection tape 320 may be formed on the fingers 313.

In the present invention, the signal collection tape of the chip carrier is used to replace the conventional power ring and ground ring, and therefore not only is the fabrication cost of the chip carrier saved, but the length of bonding wire is also decreased and the package size is reduced.

It will be apparent to those skilled in the art that various modifications and variations may be made to the structure of the present invention without departing from the scope or spirit of the invention. In view of the foregoing, it is intended that the present invention cover modifications and variations of this invention provided they fall within the scope of the following claims and their equivalents.

What is claimed is:

1. A chip carrier for carrying a chip, comprising:
a carrier, having a surface, a die pad and a plurality of electrical contacts surrounding the die pad; and
at least one signal collection tape, disposed on the surface of the carrier, and electrically connected to the chip.

2. The chip carrier as claimed in claim 1, wherein the carrier is a lead frame, and the electrical contacts are inner leads.

3. The chip carrier as claimed in claim 1, wherein the carrier is a substrate, and the electrical contacts are fingers.

4. The chip carrier as claimed in claim 1, wherein the signal collection tape is disposed on the die pad.

5. The chip carrier as claimed in claim 1, wherein the signal collection tape is disposed on the electrical contacts.

6. The chip carrier as claimed in claim 1, wherein the signal collection tape comprises a base layer and a conductive layer formed on the base layer.

7. The chip carrier as claimed in claim 6, wherein the base layer comprises an adhesive layer and an insulating layer formed on the adhesive layer.

8. The chip carrier as claimed in claim 6, wherein the conductive layer comprises a metal layer and an electroplating layer formed on the metal layer.

9. The chip carrier as claimed in claim 8, wherein the metal layer comprises an adhesive layer.

10. A chip package, comprising:
a carrier, having a surface, a die pad and a plurality of electrical contacts surrounding the die pad;
a chip, disposed on the die pad; and
at least one signal collection tape, disposed on the surface of the carrier, and electrically connected to the chip.

11. The chip package as claimed in claim 10, wherein the carrier is a lead frame, and the electrical contacts are inner leads.

12. The chip package as claimed in claim 10, wherein the carrier is a substrate, and the electrical contacts are fingers.

13. The chip package as claimed in claim 10, wherein the signal collection tape is disposed on the die pad.

14. The chip package as claimed in claim 10, wherein the signal collection tape is disposed on the electrical contacts.

15. The chip package as claimed in claim 10, wherein the signal collection tape comprises a base layer and a conductive layer formed on the base layer.

16. The chip package as claimed in claim 15, wherein the base layer comprises an adhesive layer and an insulating layer formed on the adhesive layer.

17. The chip package as claimed in claim 15, wherein the conductive layer comprises a metal layer and an electroplating layer formed on the metal layer.

18. The chip package as claimed in claim 17, wherein the metal layer comprises an adhesive layer.

19. A signal collection tape, comprising:
a base layer, having an adhesive layer and an insulating layer formed on the adhesive layer; and
a conductive layer, formed on the insulating layer of the base layer, and comprising a metal layer and an electroplating layer formed on the metal layer.

20. The signal collection tape as claimed in claim 19, wherein the metal layer comprises an adhesive layer.
